(19) United States
(12) Patent Application Publication
(10) Pub. No.: US 2014/0239157 A1
(43) Pub. Date: Aug. 28, 2014

(54) BRIGHT SOURCE PROTECTION FOR LOW LIGHT IMAGING SENSORS

(71) Applicant: THE SECRETARY OF STATE FOR DEFENCE, SALISBURY, WILTSHIRE (GB)

(72) Inventors: Christopher David Burgess, Salisbury (GB); Lee Hill, Salisbury (GB)

(21) Appl. No.: 14/347,411

(22) PCT Filed: Sep. 27, 2012
(86) PCT No.: PCT/GB2012/000745

§ 371 Date: Mar. 26, 2014

(30) Foreign Application Priority Data
Sep. 29, 2011 (GB) 1116778.0

(51) Int. Cl. H01J 40/16; H01L 27/146

(52) U.S. Cl. CPC H01J 40/16; H01L 27/14625
USPC 250/208.1

(57) ABSTRACT

This invention relates to a low light imaging sensors and particularly image intensification and CMOS sensors. To overcome issues of dazzle and halo when operating in areas where the scene encompasses bright light sources, the invention provides material layers in contact with the detector material to spatially limit the generation or subsequent diffusion of electrons in said detector material. This allows the imaging sensor to perform as normal under bright conditions, maintaining the operator's scene awareness and spatial acuity.

### TECHNICAL FIELD OF THE INVENTION

This invention relates to a low light imaging sensors and particularly image intensification and CMOS sensors.

Most imaging sensors, which include Image Intensification (I²) technology, operate by converting an optical image into an electrical signal, which is then amplified and then reconverted back to a visible image. I² tubes for night vision devices, when operated in the presence of high intensity light sources, often have degraded performance due to optical effects like blooming, halo and loss of image contrast through automatic gain control. High intensity light sources such as display screens, street lights, welding arcs or car head lamps, can also lead to complete loss of contrast and the creation of permanent damage marks on the detector material of the sensor. These effects cause degradation of image quality or loss of situational awareness for the user rendering them unusable in their intended role.

In typical modem photo-cathode image intensifiers like those which use Gallium Arsenide (GaAs), there exists a high potential difference between the photo-cathode and the front face of the micro-channel-plate (MCP) otherwise known as an electron receiving device. The front face is defined as the surface which is nearest to the incident photons of the scene to be viewed. There also exists high potential differences between the front and rear faces of the MCP and between the rear face of the MCP and the aluminised phosphor screen. During use of an I² tube in ideal conditions, photons incident on the photo-cathode material of conventional image intensification tubes raise electrons from the valence band to the conduction band of the material. These photo-generated electrons quickly thermalise and diffuse towards the emission surface (rear face) of the photo-cathode. There they are emitted into the vacuum and accelerated by an applied electric field to the MCP. Within the MCP the electronic signal is amplified through secondary electron emission from the bombardment of the MCP material. Further field induced acceleration of the secondary electrons occurs in the MCP due to the high potential difference provided by the power source. Electrons exiting the MCP are accelerated towards a phosphor screen (display electrode assembly) converting the electronic image back to a visible image. A fibre twist then inverts the resulting image so that it can be viewed by the user.

Those aware of current image intensification technology will realise that other configurations of output are exploited. For example the assembly may include coupling a charge coupled device (CCD) directly to the phosphor coating. Furthermore, recent advancements in image sensor technology allow the photo-cathode material to be placed in proximity focus with a high resolution complementary metal oxide semiconductor (CMOS) chip anode. The electrons emitted by the photo-cathode are directly injected in the electron bombardment mode into the CMOS anode. Here the electrons are collected, amplified and read out to produce a direct digital video output that can be viewed by the user in any number of ways.

Exposure of the photo-cathode material to bright light source causes blooming and halo effects; these are facets of the proximity focused image intensifier tube. A bright light source creates a large number of photo-generated electrons, which in turn are emitted from the photo-cathode back surface and accelerated towards the MCP input. Some of these primary photo-electrons are reflected at the surface of the MCP back towards the photo-cathode but without enough energy to reach it. The trajectory of these electrons is parabolic and hence they return to the face of the MCP within a circular area whose centre is the reflection point. These reflected electrons can then cause secondary emission in the MCP resulting in the formation of a halo in the converted image.

In many cases over-exposure to bright light sources can directly lead to permanent ‘scarring’ of the photo-cathode material. Prolonged exposure can cause burn marks to appear on the photo-cathode. This damage is caused by impurity ions, generally potassium, transferred from the MCP to the photo-cathode resulting in regions of low sensitivity and even permanent black scarring corresponding to the bright regions of the scene; this is caused by the bombardment and sputtering of the activation surface of the photo-cathode.

Modern I² devices use several methods to counteract the effects of bright light sources. They can employ thin filths of aluminium oxide on the MCP surface for ion absorption. In addition ionic diffusion in the photo-cathode can reverse damage of the impurity ions over time. Even so these films almost certainly let through large numbers of ions and more often the tube is taken out of service due to its reduced performance. Automatic brightness control is achieved by adjusting the voltage across the MCP so that amplification of the electrical signal is reduced, which in turn reduces the amount of secondary electron emission. Protection from bright sources can be achieved by adjusting the voltage between the photo-cathode and the MCP; this reduces the initial amount of photo-generated electrons emitted from the photo-cathode. Gating the voltage to the photo-cathode by changing the length of time the high voltage supply is connected across the photo-cathode and MCP i.e. the duty cycle, prevents continuous emission of electrons due to bright light sources which greatly enhances the operational dynamic range of the tube in terms of the ambient illuminations it can be used in. The duty cycle of the voltage to the photo-cathode is regulated in respect to the current as drawn by the photo-cathode; this duty cycle has a minimum level for useful operation as an imaging device. U.S. Pat. No. 5,146,077 (Caserta et al.) discloses a gated voltage apparatus for high light resolution and bright source protection of image intensifier tubes. Caserta presents a bright source protection circuit that modulates the voltage supplied to the tube's photo-cathode in response to the current drawn. In realisation the photo-cathode is pulsed on and off until the desired photo-cathode current is reached. However, the effect of this is twofold; it is recognised that the reduction of the MCP voltage results in the appearance of fixed pattern noise (the matrix pattern of the MCP) in the image and it is also observed that contrast in non-bright areas of the image is lost due to the reduction in gain; an effect known as ‘dazzle’.

Blooming and dazzle are common problems for intensification devices; as such bright sources are a significant problem for the use of night vision equipment. This has led to another approach, which is to provide such systems and devices with electro-optic protection measures (EOPM) to limit or filter the transmission of light to the device. However the limitation of light incident onto the photo-cathode of an image intensification tube inherently degrades the performance of the device and restricts its operational envelope. Therefore intensification tube manufacturers do not incorporate EOPM into tube technology. U.S. Pat. No. 6,667,472 (Janeczko et al) aims to reduce stray light and ghost like patterns caused by bright lights in or near the field of view of a night vision device. Janeczko discloses an image intensifier tube having a photo-cathode input window (directly facing the front optical input element) which bears a broadband anti-reflection coating, either on the window material or on a glass plate adhered to the window. In addition to an anti-reflection coating Janeczko discloses a laser reflective coating, which may be employed on the photo-cathode window in addition to or instead of the broadband anti-reflection coating, either disposed on a plate or on the photo-cathode window itself.

However, the performance of a reflecting filter is highly dependent on the incident direction and the incident wavelength and to employ such a laser protective filter the manufacturers must have some knowledge about the laser source, which is not always available. Although it is possible to make a reflecting filter that provides the high optical rejection needed to protect an image intensifier, adequately suppressing off-axis light is a real problem for the filter design. Furthermore reflecting filters are expensive and the potential for detection of the reflected signal is a further disadvantage in certain applications. Although protection from blooming, dazzle and damage at key wavelengths can easily be achieved, the methods are limited in their application through the amount of optical loss they cause the device. Key wavelength protection cannot afford the same protection for broadband light sources owing to the wavelength bandwidth of the source—successive implementation of multiple interfering or absorbing filters to protect from several key wavelengths will introduce an optical loss that cannot be tolerated by the user of the sensor.

### SUMMARY OF THE INVENTION

In view of the vulnerabilities of I² devices and the limitations of the application of protection measures as described above, it is therefore desirable to have an image intensification tube that employs material layers and control electronics that can spatially limit the photo-cathode response for bright areas in an imaged scene.

Instead of spectrally limiting the light incident onto the photo-cathode through filters placed beforehand, it is possible to spatially limit light from areas of the scene where the sources are located. This requires protection measures that are located at a focal plane of the imaging system, i.e. at an intermediate focal plane or at the detector material to spatially limit the generation or subsequent diffusion of electrons in the photo cathode material. Spatial protection effectively blocks out areas of the image where bright sources are located whilst allowing low intensity light from other areas of the scene to pass and form an image on the detector.

Accordingly the present invention provides a low light imaging sensor comprising: a photo-cathode layer, an electron receiving device arranged to receive electrons from the photo-cathode layer, wherein the low light imaging sensor further comprises: a transparent electrode, a layer of photo-sensitive material, the layer of photo-sensitive material being positioned between the photo-cathode layer and the transparent electrode, and a means to apply a potential difference between the photo-cathode layer and the transparent electrode during operation.

The introduction of a photo-sensitive layer (PSL), positioned in between a transparent electrode and the photo cathode allows localised photo-generated charge to move from the photo-cathode through the PSL and onto the transparent electrode under the action of an applied field. The movement of photo-generated charge occurs locally in areas of the focal plane where relatively high irradiances are seen from a bright light source in the scene. Therefore the provision of a photo-sensitive material layer into the design of an image intensification tube affords the device spatial bright source protection (BSP) without compromising the optical intensification in low light areas of the scene. Spatial BSP can be realised through this use of the photo-sensitive material layer that, upon illumination, provides a method of locally limiting the number of, or the subsequent diffusion of the photo-generated electrons within the photo-cathode. The advantage of a night vision device employing an I² tube with spatial BSP is to allow the device to operate as normal for low light areas of the scene, retaining image contrast and scene situational awareness should an intense light source be directed towards the device. By spatially limiting the electron emission from the photo-cathode under intense illumination the photo-cathode does not need to be power limited by traditional BSP electronics, thereby allowing normal operation under the bright conditions so that the operators' spatial acuity and contrast sensitivity are not affected. Where the electron receiving device is a MCP, the lifetime of the I² tube will be extended through the reduction of ion damage to the photo-cathode caused by the excesses of emitted electrons from the photo-cathode incident on the MCP. This also removes the need for an ion absorbing thin film, which allows the increased sensitivity of the I² tube. Furthermore, the voltage across the MCP does not need to be reduced due to increasing brightness levels thereby allowing the tube to continue to operate under normal gain conditions, increasing image contrast for the dark areas of the scene and reducing the chance of dazzle and the size of any halo effects. Additional benefits of the inclusion of a photo-sensitive layer are also realised. A variable degree of control over the voltage applied across the photo-sensitive layer and the photo-cathode adds the benefit that the amount of spatial protection can be easily adjusted, possibly in response to increasing current drawn by the photo-cathode. Reversing the polarity of the applied voltage also improves sensor dynamic range in extremely dark conditions. Upon leaving the back surface of the MCP the electronic image can be converted into a visible image through the fluorescence of the phosphor brought on by electron, bombardment of an aluminised phosphor coating or phosphor screen.

Optionally placing the photo-cathode material in proximity focus with an active pixel sensor, such as a high resolution complementary metal oxide semiconductor (CMOS) chip anode. The electrons emitted by the photo-cathode will be directly injected in the electron receiving mode into the CMOS anode. Here the electrons are collected, amplified and read out to produce a direct digital video output that can be viewed by the user in any number of ways. The advantage of using an electron receiving device such as a CMOS chip is that the vision sensor can be used in ambient light conditions such as dusk or daylight.

When a layer of dielectric material is positioned between the photo-cathode and PSL, the dielectric material electrically separates the PSL and photo-cathode layers. In this scheme the intention is to create a surface potential at the front of the photo cathode material (i.e. GaAs) and a depletion region within the bulk material of the photo cathode. In bright areas of the image an applied field placed across the electrode and the photo-cathode creates this surface potential and influences the diffusion of photo generated electrons in the photo-cathode. The influence on the diffusion electrons in the bulk semi-conductor material is in the opposite direction of the photo-cathode's emission surface. If a MCP is used as the electron receiving device, the overall probability of escape and amplification at the MCP reduces and therefore damaging effects to the MCP are reduced. This influence only happens in areas of the focal plane where relatively high irradiances are seen from a bright light source in the scene.

A variety of materials can be used for the photosensitive layer including doped Poly Vinyl Carbazole (PVK) where the dopant can be dyes tailored to the waveband of interest; a thin layer of doped Gallium Arsenide (GaAs); the dopant can be variable amounts of Aluminium, Indium or other elements; doped Silicon Carbide, the dopant can be any transition metal; doped Gallium Phosphide (GaP) or either doped or un-doped Bismuth Silicon Oxide (BSO).

The present invention may be implemented in several different forms, disclosed here by way of example is a detailed description of the invention using four alternative embodiments.

### BRIEF DESCRIPTION OF THE FIGURES

FIG. 1 is a representation of a standard image intensification tube known in the art;

FIG. 2 is an example layout of an intensification tube according to a first embodiment of the present invention;

FIG. 3 illustrates part of the first embodiment of the invention;

FIG. 4 is a sketch showing the action of the photo-generated electrons in the photo-cathode and photo-sensitive layer under the applied fields in low and high intensity illumination cases for the first embodiment of the present invention;

FIG. 5 is an example layout of an intensification tube according to a second embodiment of the present invention;

FIG. 6 illustrates part of the second embodiment of the present invention;

FIG. 7 is a sketch showing the action of the photo-generated electrons in the photo-cathode, photo-sensitive layer and dielectric materials under the applied fields in low and high intensity illumination cases for the second embodiment of the present invention.

FIG. 8 is an example layout of an electron receiving silicon image chip according to a third embodiment of the present invention;

FIG. 9 is an example layout of an electron receiving silicon image chip with an additional insulating layer according to a forth embodiment of the present invention;

### DETAILED DESCRIPTION OF THE PREFERRED EMBODIMENT OF THE INVENTION

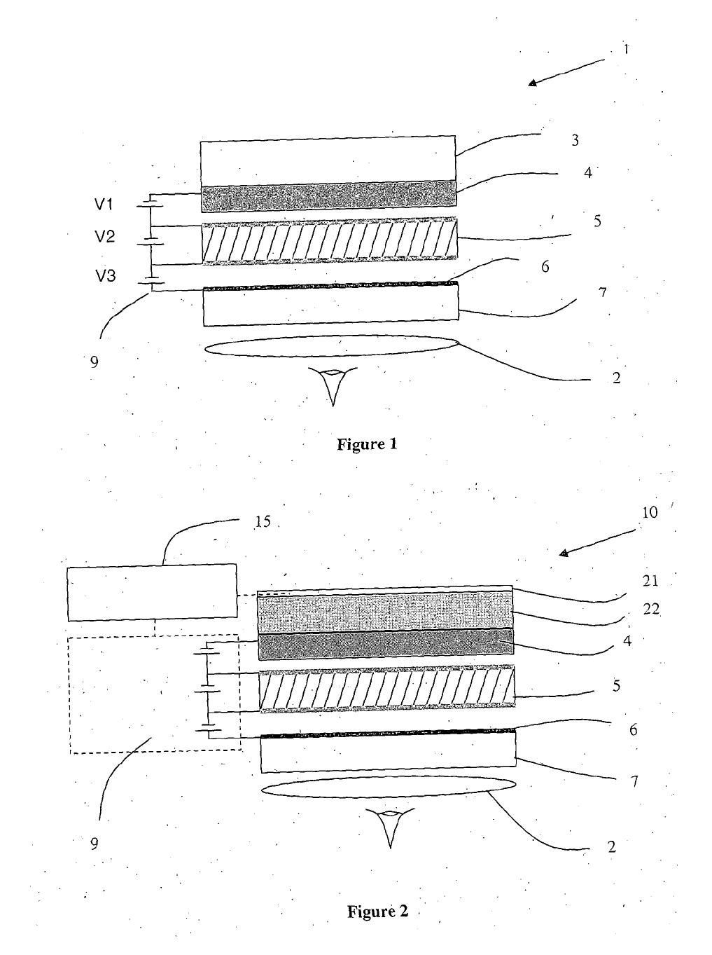

FIG. 1 shows a schematic diagram of a basic image intensification tube 1 known in the art. A night vision device generally comprises of an objective lens (not shown), which focuses incoming light from the viewed scene on to input end of the I² tube. The I² tube provides a visible monochrome image at the output end, which replicates the scene. This image is then presented to the user through eye-piece optics—here shown as a simple lens 2. Under normal human diurnal vision this low light scene without the aid of image intensification would not generally be visible.

In the configuration shown in FIG. 1 the transmission photo-cathode material 4 is in contact with the transparent window material 3. The photo-cathode material 4 is situated in a vacuum chamber (not shown). Those skilled in the art will understand that there can exist, index lattice-matching and passivation layers between the photo-cathode and the transparent window, these are not shown. Incident photons from the scene to be viewed are absorbed in the photo-cathode material 4 and subsequently generate charge carriers. Electrons generated by the incoming photon are quickly thermalised into conduction band minima and constitute a diffusion flux towards the emission surface of the photo-cathode 4. Those skilled in the art will understand that activation layers, serving to lower the electron affinity in the surface region, can be present to facilitate the emission of electrons into the vacuum through band bending. Electrons emitted into the vacuum are accelerated by an electric field setup by the potential difference 9 (power supply) across the photo-cathode 4 and the Micro Channel Plate (MCP) 5. The potential differences are shown in this example as voltage levels V1, V2 and V3. Electrons entering the MCP 5 and impacting on the surface of its material coating can subsequently cause the emission of secondary electrons. An accelerating field setup within the MCP 5 through the potential difference between the two MCP surfaces results in a cascade generation of electrons across the width of the MCP. Upon leaving the back surface of the MCP the secondary electrons are again accelerated by an electric field setup through the potential difference between the back surface of the MCP and the display electrode assembly 6 (usually an aluminised phosphor coating or phosphor screen). There the electronic image is converted into a visible image through the fluorescence of the phosphor brought on by electron bombardment. This visible image, owing to the objective lens, is inverted and is hence re-inverted by the exit fibre twist 7. Eye-piece optics 2 then focuses the image formed from the exit fibre twist for human vision.

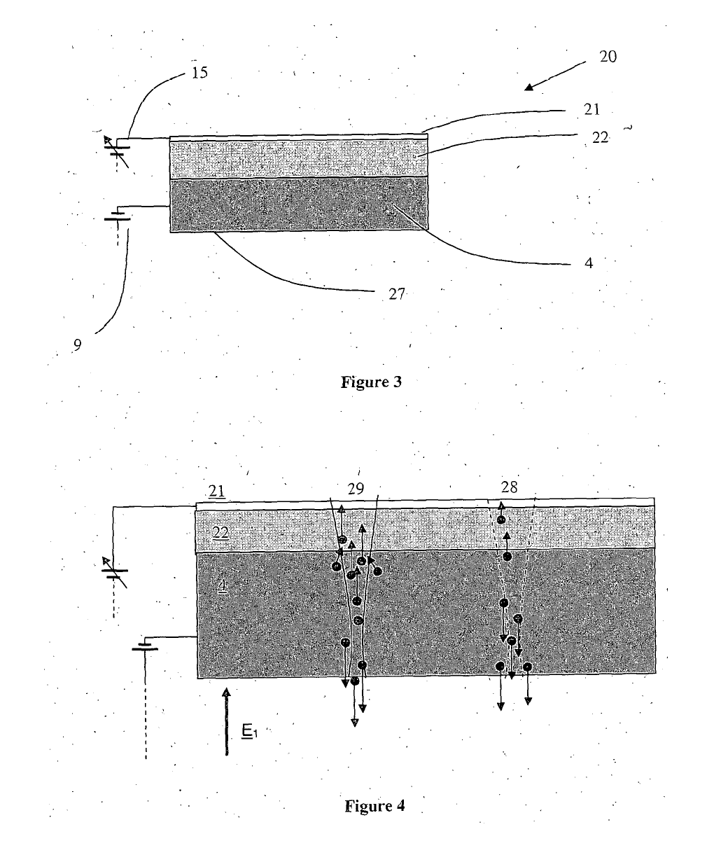

FIG. 2 shows a schematic view of a first embodiment of the present invention 10 with the common features of FIG. 1. FIG. 2 also shows an electrical connection to a transparent electrode 21 from control circuitry 15, the transparent electrode 21 being transparent in the visible and near IR regions of the electromagnetic spectrum. Also a PSL 22 is in direct contact with the photo-cathode 4 and the electrode 21. The control circuitry consists of circuit elements coupled to the power supply 9 to provide an adjustable voltage of the right polarity to the electrode 21. The introduction of the PSL 22, under areas of high illumination levels produces the subsequent generation and movement of photo generated carriers in the PSL 22 but under the applied field generated by the power supply 9 across the electrode 21 and the photo-cathode 4. Under normal operation (dark conditions) there exists a potential barrier between the PSL 22 and the photo-cathode 4 that reduces charge migration between the two materials. In addition the PSL 22 under these conditions remains non-conducting so a current is not sustained across the layers. In response to high illumination levels, the PSL 22 becomes conducting and its electrical potential barrier decreases allowing increased localised photo-generated charge to move from the photo-cathode 4 to the PSL 22 and onto the transparent electrode 21 under the action of the applied field. The adjustable voltage allows the amount of spatial BSP to be tuned and the integration with the power supply 9 means that the voltage supply to the electrode 21 can be gated in a similar fashion to the voltage to the photo-cathode 4. The advantage of a gated supply is that any photo generated charge in the PSL 22 is given time to diffuse or re-combine in between voltage pulses so that the limiting effect does not persist without the presence of the bright light source in the scene. A person skilled in the art will appreciate that other types of control circuitry may be used. FIG. 3 shows a more detailed representation of part of the first embodiment, showing the emission surface 27 of the photo-cathode 4. FIG. 4 shows the representation of the embodiment in FIG. 3 where movement of electrons is compared under normal illumination conditions 28 and under a focal spot of bright light 29. When high intensity light is detected, the diffusion of electrons tends to be in the opposite direction of the emission surface 27 of the photo-cathode 4 thereby reducing the probability of escape and amplification at the MCP 5.

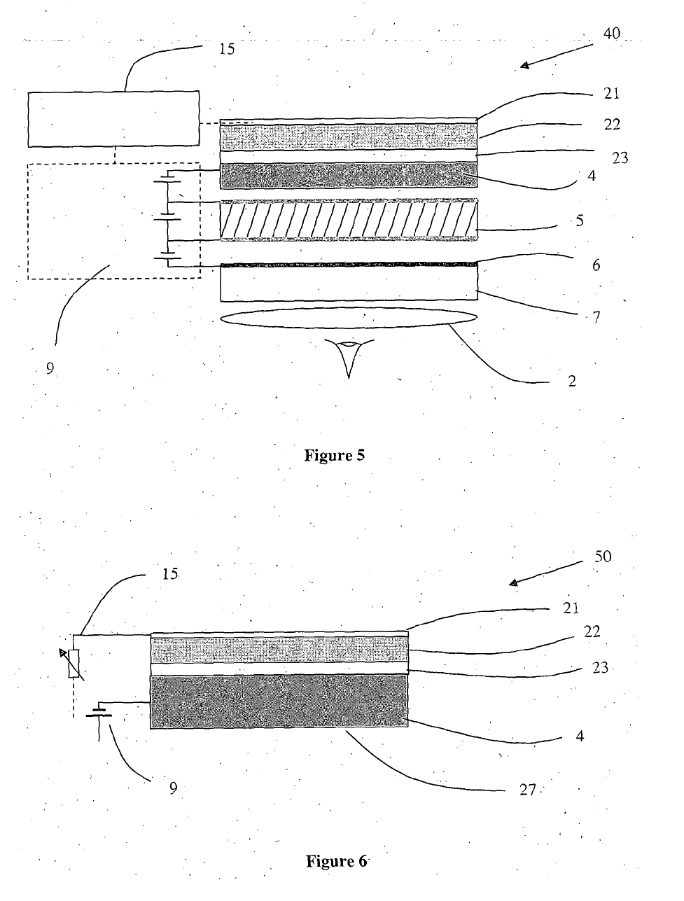

FIG. 5 shows a second embodiment of the present invention 40. FIG. 6 shows a more detailed representation 50 of the second embodiment of the invention. Additionally compared to the first embodiment, the PSL 22 is positioned in contact with a layer of dielectric material 23, which in turn is positioned in contact with the photo-cathode material 4. The dielectric material 23 electrically separates the PSL 22 and photo-cathode 4 layers. The power supply 9 generates an applied field across the electrode 21 and the photo-cathode 4 which will cause an accumulation of positive carriers at the back surface of the dielectric material 23, i.e. in the vicinity of the interface between the dielectric material 23 and the photo-cathode 4. The generated electric potential due to the accumulation of charge extends into the photo-cathode 4, subsequently providing an electric displacement that influences the diffusion of photo generated electrons in the photo-cathode 4. The influence on the diffusion electrons is in the opposite direction of the emission surface 27 of the photo-cathode 4, thereby reducing the probability of escape and amplification at the MCP 5. This influence only happens in areas of the focal plane where relatively high irradiances are seen from a bright light source in the scene. Low intensity light generates fewer electrons in the PSL 22 so that a smaller amount of charge is found at the front surface of the dielectric layer 23. The resulting displacement field is too weak to affect the normal diffusion of photo generated electrons in the photo-cathode material 4. In this way the image formed from the scene under normal ambient illumination is seen while parts of the image with bright light sources are dimmed without affecting the gain of the tube. FIG. 7 shows the representation of the embodiment in FIG. 6 where movement of electrons is compared under normal illumination conditions 28 and under a focal spot of bright light 29. When high intensity light is detected, the diffusion of electrons tends to be in the opposite direction of the emission surface 27 of the photo-cathode 4 thereby reducing the probability of escape and amplification at the MCP 5.

The control circuitry 15 in both embodiments consists of circuit elements similarly coupled to the power supply 9 to provide an adjustable voltage of the right polarity to the electrode 21. By taking reference to the power supply 9, the limiting layer control circuitry 15 can take a reference to the frequency and the duty cycle of the supply voltage across the photo-cathode 4 and the MCP 5. This reference can be used to drive a pulsed voltage of the right polarity and duty cycle to the electrode 21. In both embodiments an AC square wave with the right phase, bias and duty cycle could be applied to the electrode 21. The advantage of an AC square wave is the addition of a ‘refresh’ pulse to the PSL and electrode layers in between the traditional voltage pulses to the photo-cathode 4. The purpose of the refresh pulse is to ‘flush’ any accumulated charges from the front surface of the PSL 22 in the first embodiment or the front surface of the dielectric material 23 in the second embodiment. The front surface is regarded as being the surface in contact with the photo-cathode 4.

In both embodiments the effect of the displacement field of the photo-generated electrons can be controlled through adjusting the voltage across the PSL 22. For the spatial BSP application the electrode 21 should take a positive polarity supply; reversing the polarity of this voltage would reverse the effect to provide an accelerating displacement field for the photo-generated electrons, thereby enhancing the performance of the device under low light conditions. This action could recover some of the performance losses inherent through the optical, absorption within the PSL 22. An I² tube incorporating such additional layers could be operated in this reverse bias mode until a bright light source is detected within the scene upon which the bias is switched so the PSL, electrode and in the second embodiment dielectric layer can provide the required spatial BSP.

In operation, an image intensifier utilising spatially bright source protection allows the user to retain spatial acuity and scene awareness when operating in environments around bright light sources. Such a device can function in these environments without the penalties involved in the addition of optical elements or modifying the tube power supply as in the prior art.

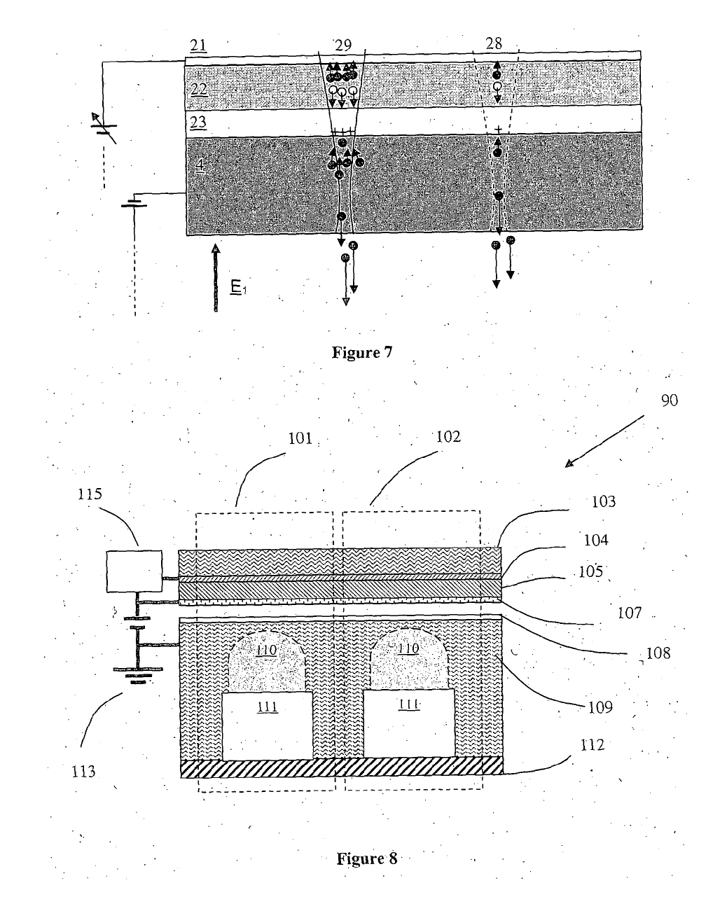

FIG. 8 shows a schematic view of an electron receiving silicon image chip 90, the example layout shows two pixel regions 101 and 102 side by side (indicated by the dashed lines). Each pixel has a transparent window 103 constructed of glass, a transparent electrode 104 constructed of indium tin oxide (ITO, being transparent in the visible and near IR regions of the electromagnetic spectrum), a photo-sensitive layer 105 and photo-cathode material 107 constructed in layers. The image chip 90 also consists of several materials that make up a standard CMOS architecture; these include a passivation layer 108, a layer of epitaxial silicon 109 (P-type semiconductor substrate), an active region 110 (which is a diode of n+ semiconductor material), a gate electrode assembly 111 and read out electronics 112. The passivation layer 108 is used to reduce surface recombination in the layer of epitaxial silicon 109. FIG. 8 also shows control circuitry 115 consisting of circuit elements coupled to the power supply 113 to provide an adjustable voltage of the right polarity to the electrode 104, the photo-cathode material 107, the gate electrode assembly 111 and the read out electronics 112 (electrical connections to the gate electrode assembly 111 and the read out electronics. 112 are not shown for simplification). The epitaxial silicon 109 is connected to ground.

During operation under normal illumination levels (dark conditions), incident photons from the scene to be viewed are absorbed in the photo-cathode material 107. During such conditions, there exists a potential barrier between the photo-sensitive layer 105 and the photo-cathode 107 that reduces charge migration between the two materials. In addition the photo-sensitive layer 105 under these conditions remains non-conducting so a current is not sustained across the layers. The photons absorbed into the photo-cathode material 107 are subsequently generated into charge carriers. Electrons generated by the incoming photons are emitted from the photo-cathode 107 and transferred to the active region 110 via the passivation layer 108 and the epitaxial silicon 109. The transfer of electrons is achieved by a potential difference (a voltage provided by the power supply 113 and the control circuitry 115) across the photo-cathode 107 and the epitaxial silicon 109. The electrons are then transferred from the active region 110 by the gate electrode assembly 111 in the standard way for an electron receiving silicon image sensor chip. From the read out electronics 112, the electronic image can be converted into a visible image through a digital video output (not shown).

When a pixel is under high illumination levels this produces the subsequent generation and movement of photo generated carriers in the photo-sensitive layer 105, the photo-sensitive layer 105 becomes conducting and its electrical potential barrier decreases allowing increased localised photo-generated charge to move from the photo-cathode 107 to the photo-sensitive layer 105 and onto the transparent electrode 104 under the action of an applied field. The applied field is generated by the power supply 113 and control circuitry 115 across the electrode 104 and the photo-cathode 107, the electrode 104 voltage being higher than the photo-cathode 107 to draw the electrons towards the electrode 104. In other words a short circuit is created at high illumination levels between the electrode 104 and photo-cathode 107, reducing the number of electrons in the active region 110. In response to high illumination levels, dependent on the current level at the electrode 104, the adjustable voltage from the circuitry 115 and the integration with the power supply 113 allows the amount of spatial BSP to be tuned and so the voltage supply to the electrode 104 can be gated in a similar fashion to the voltage to the photo-cathode 107.

The advantage of a gated supply is that any photo generated charge in the photo-sensitive layer 105 is given time to diffuse or re-combine in between voltage pulses so that the limiting effect does not persist without the presence of the bright light source in the scene. A person skilled in the art will appreciate that other types of control circuitry may be used.

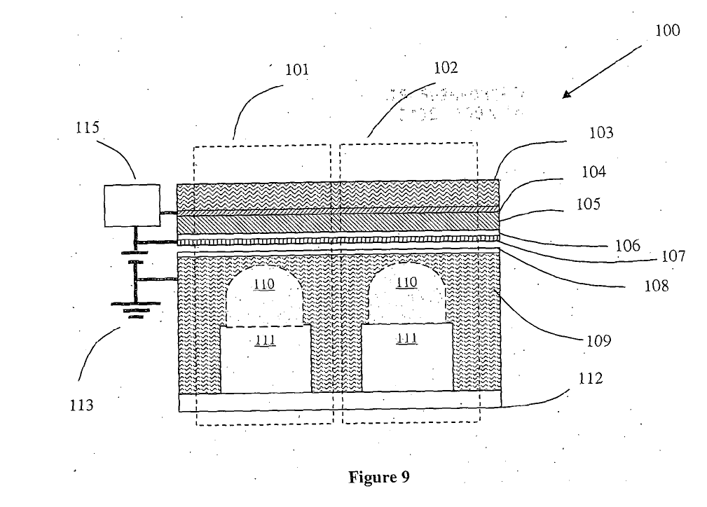

FIG. 9 shows a forth embodiment of the present invention 100, with components in common with FIG. 8 using the same numerals. The photo-sensitive layer 105 is positioned in contact with a layer of dielectric material 106, which in turn is positioned in contact with the photo-cathode material 107. The dielectric material 106 electrically separates the photo-sensitive layer 105 and photo-cathode 107 layers. When the power supply 113 generates an applied field across the electrode 104 and the photo-cathode 107, this will cause an accumulation of positive carriers at the back surface of the dielectric material 106, i.e. in the vicinity of the interface between the dielectric material 106 and the photo-cathode 107. The generated electric potential due to the accumulation of charge extends into the photo-cathode 107, subsequently providing an electric displacement that influences the diffusion of photo generated elections in the photo-cathode 107. The influence on the diffusion electrons within the photo-cathode 107 is in a direction away from the passivation layer 108. This influence only happens in areas of the focal plane where relatively high irradiances are seen from a bright light source in the scene. Low intensity light generates fewer electrons in the photo-sensitive layer 105 so that a smaller amount of charge is found at the surface interface of the dielectric layer 106 and photo-cathode 107. The resulting displacement field is too weak to affect the normal diffusion of photo generated electrons in the photo-cathode material 107. In this way the image read out from read out electronics 112 under normal ambient illumination is seen however under high illumination levels the parts of the image with bright light sources are dimmed without affecting the rest of the image.

The embodiments of FIGS. 8 and 9 could utilise an AC square wave with the right phase, bias and duty cycle applied to the electrode 104. The advantage of an AC square wave is the addition of a ‘refresh’ pulse to the photo-sensitive layer 105 and the electrode 104 in between the traditional voltage pulses to the photo-cathode 107, the gate electrode assembly 111 and the read out electronics 112. The purpose of the refresh pulse is to ‘flush’ any accumulated charges from the interfacing surface of the photo-sensitive layer 105 and photo-cathode 107 in the third embodiment or the interfacing surface of the dielectric material 106 and photo-cathode 107 in the forth embodiment.

1. A low light imaging sensor comprising:
a photo-cathode layer, an electron receiving device arranged to receive electrons from the photo-cathode layer,
wherein the low light imaging sensor further comprises:
a transparent electrode, a layer of photo-sensitive material, the layer of photo-sensitive material being positioned between the photo-cathode layer and the transparent electrode, and a means to apply a potential difference between the photo-cathode layer and the transparent electrode during operation.

2. A low light imaging sensor according to claim 1 wherein the electron receiving device is a micro-channel plate.

3. A low light imaging sensor according to claim 1 wherein the electron receiving device is a complementary metal-oxide-semiconductor (CMOS) sensor.

4. A low light imaging sensor according to claim 1 wherein the image intensification device further comprises the means to form a visible image from an electronic image connected to the output of the electron receiving device.

5. A low light imaging sensor according to claim 4 wherein the means to form a visible image from an electronic image is a phosphor screen.

6. A low light imaging sensor according to claim 4 wherein the means to form a visible image from an electronic image is a digital video output.

7. A low light imaging sensor according to claim 1 wherein the low light imaging sensor further comprises:
a layer of dielectric material, the layer of dielectric material being positioned between the layer of photo-sensitive material and the transparent electrode.

8. A low light imaging sensor for a night vision sensor according to claim 1 wherein the layer of photo-sensitive material is comprised of doped Poly Vinyl Carbazole (PVK).

9. A low light imaging sensor for a night vision sensor according to claim 1 wherein the layer of photo-sensitive material is comprised of doped Gallium Arsenide (GaAs).

10. A low light imaging sensor for a night vision sensor according to claim 1 wherein the layer of photo-sensitive material is comprised of doped Silicoil Carbide.

11. A low light imaging sensor for a night vision sensor according to claim 1 wherein the layer of photo-sensitive material is comprised of doped Gallium Phosphide (GaP).

12. A low light imaging sensor for a night vision sensor according to claim 1 wherein the layer of photo-sensitive material is comprised of doped Bismuth Silicon Oxide (BSO).

13. A low light imaging sensor for a night vision sensor according to claim 1 wherein the layer of photo-sensitive material is comprised of undoped Bismuth Silicon Oxide (BSO).

14. (canceled)
